(19) United States
(12) Patent Application Publication
(10) Pub. No.: US 2018/0197734 A1
(43) Pub. Date: Jul. 12, 2018

(54) BUFFER LAYER TO INHIBIT WORMHOLES IN SEMICONDUCTOR FABRICATION

(71) Applicant: GLOBALFOUNDRIES Inc., Grand Cayman (KY)

(72) Inventors: Bhupesh CHANDRA, Wappingers Falls, NY (US); Annie LEVESQUE, Hopewell Junction, NY (US); Matthew W. STOKER, Malta, NY (US); Shreesh NARASIMHA, Hopewell Junction, NY (US); Viorel ONTALUS, Hopewell Junction, NY (US); Michael STEIGERWALT, Hopewell Junction, NY (US); Joshua BELL, Hopewell Junction, NY (US)

(73) Assignee: GLOBALFOUNDRIES Inc., Grand Cayman (KY)

(21) Appl. No.: 15/405,026

(22) Filed: Jan. 12, 2017

(51) Int. Cl. H01L 21/02; H01L 29/66

(52) U.S. Cl. CPC H01L 21/02167; H01L 29/66568

(57) ABSTRACT

Reducing wormhole formation during n-type transistor fabrication includes providing a starting structure, the starting structure including a semiconductor substrate, a n-type source region and a n-type drain region of a transistor. The method further includes removing a portion of each of the n-type source region and the n-type drain region, the removing creating a source trench and a drain trench, and forming a buffer layer of silicon-based material(s) over the n-type source region and n-type drain region that is sufficiently thick to inhibit interaction between metal contaminants that may be present below surfaces of the n-type source trench and/or the n-type drain trench, and halogens subsequently introduced prior to source and drain formation. A resulting semiconductor structure is also provided.

### BACKGROUND OF THE INVENTION

### Technical Field

The present invention generally relates to reducing or preventing defects in semiconductor fabrication. More particularly, the present invention relates to reducing or eliminating wormholes due to metal contaminants in trenches of n-type sources and drains.

### Background Information

In semiconductor fabrication, it is frequently difficult to avoid unwanted contaminants. One such case is during the forming of epitaxial semiconductor material in a trench of source/drain regions of an n-type transistor to stress the channel. Interaction between hydrochloric acid, used at high temperatures during nFET source-drain epitaxy process, and any metal contaminants in the source/drain regions can cause a wormhole between source and drain. A wormhole is an etched silicon micro/nano tunnel connecting, in a worst case, source and drain regions. If phosphorus diffuses into the wormhole, a short between the source and drain is formed. Wormholes in silicon could form during any process where silicon is exposed to a high temperature HCl in the presence of transition metal (e.g., Fe, Ni, etc.) impurities that can act as a catalyst for Si etch.

Thus, a need exists for a way to reduce or prevent wormholes from forming.

### SUMMARY OF THE INVENTION

The shortcomings of the prior art are overcome and additional advantages are provided through the provision, in one aspect, of a method of reducing wormhole formation during n-type transistor fabrication. The method includes providing a starting structure, the starting structure including a semiconductor substrate, a n-type source region and a n-type drain region of a transistor in the semiconductor substrate. The method further includes removing a portion of the n-type source region and a portion of the n-type drain region, creating a source trench and a drain trench, and forming a buffer layer over a surface of the source trench and the drain trench, the buffer layer being sufficiently thick to inhibit interaction between metal contaminants that may be present below surfaces of the n-type source trench and/or the n-type drain trench, and halogens during a subsequent process.

In accordance with another aspect, a semiconductor structure is provided. The semiconductor structure includes a semiconductor substrate, a n-type source region having a source trench, and a n-type drain region having a drain trench. One or more metal contaminants may be present below surfaces of the source trench and/or the drain trench. The semiconductor structure further includes a buffer layer covering the surfaces of the source trench and the drain trench.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a transistor in fabrication, the transistor including a semiconductor substrate, a n-type source region with a trench therein, and a n-type drain region with a trench therein. The trenches are formed to house epitaxial semiconductor material for stressing a channel region, in accordance with one or more aspects of the present invention.

FIG. 2 depicts one example of either the source region or drain region (both look the same throughout; only one shown for simplicity) of FIG. 1 after forming a relatively thick buffer layer of, for example, phosphorus-doped epitaxial silicon carbon, prior to the introduction of hydrochloric acid (more generally, halogens) at high temperatures during nFET source/drain epitaxy process, the buffer layer reducing or eliminating interaction between any metal contaminants present under the source trench and/or drain trench, and the hydrochloric acid present during epitaxial growth, and, thus, retarding wormhole formation, in accordance with one or more aspects of the present invention.

FIG. 3 depicts another example of either the source region or drain region of FIG. 1 after forming a buffer layer, the buffer layer including a relatively thick bottom layer of phosphorus-doped silicon covering surfaces of the source trench and the drain trench and any contaminants that may be present, and a top layer of phosphorus-doped epitaxial silicon carbon, prior to the introduction of hydrochloric acid at high temperatures during nFET source/drain epitaxy process, the buffer layer reducing or eliminating interaction between any metal contaminants that may be present under surfaces of the source trench and/or the drain trench, and the hydrochloric acid, in accordance with one or more aspects of the present invention.

FIG. 4 depicts still another example of either the source region or drain region of FIG. 1 after forming a buffer layer, the buffer layer including a relatively thick bottom layer of undoped epitaxial silicon carbon covering any metal contaminants that may be present under surfaces of the source trench and/or the drain trench, and a top layer of phosphorus-doped epitaxial silicon carbon, prior to the introduction of hydrochloric acid at high temperatures during nFET source/drain epitaxy process, the buffer layer reducing or eliminating interaction between metal contaminants near the trench and the hydrochloric acid, in accordance with one or more aspects of the present invention.

FIG. 5 is one example of a flow diagram describing aspects of the method of the present invention. Initially, a starting structure is provided having a substrate and n-type and p-type source and drain regions, then part of each source and drain region is removed, creating source and drain trenches, and a buffer layer is formed that is sufficiently thick to inhibit metal contaminant/halogen interaction in subsequent processes of forming a source and a drain.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value.

Reference is made below to the drawings, which are not drawn to scale for ease of understanding, wherein the same reference numbers are used throughout different figures to designate the same or similar components.

Aspects are described herein with reference to flowchart illustrations and/or block diagrams of methods according to one or more embodiments. It will be understood that each block of the flowchart illustrations and/or block diagrams, and combinations of blocks in the flowchart illustrations and/or block diagrams, may be implemented in various ways, including the example herein.

The flowchart and block diagrams in the figures illustrate the architecture, functionality, and operation of possible implementations of methods according to various embodiments. In this regard, each block in the flowchart or block diagrams may be accomplished in ways other than those specifically set out. It should also be noted that, in some alternative implementations, the aspects noted in the block may occur out of the order noted in the flow diagram. For example, two blocks shown in succession may, in fact, be performed substantially concurrently, or the blocks may sometimes be performed in the reverse order, depending upon the particular circumstances involved. It will also be noted that each aspect of the flow diagram, and combinations of aspects of the flow diagram, can be implemented as described.

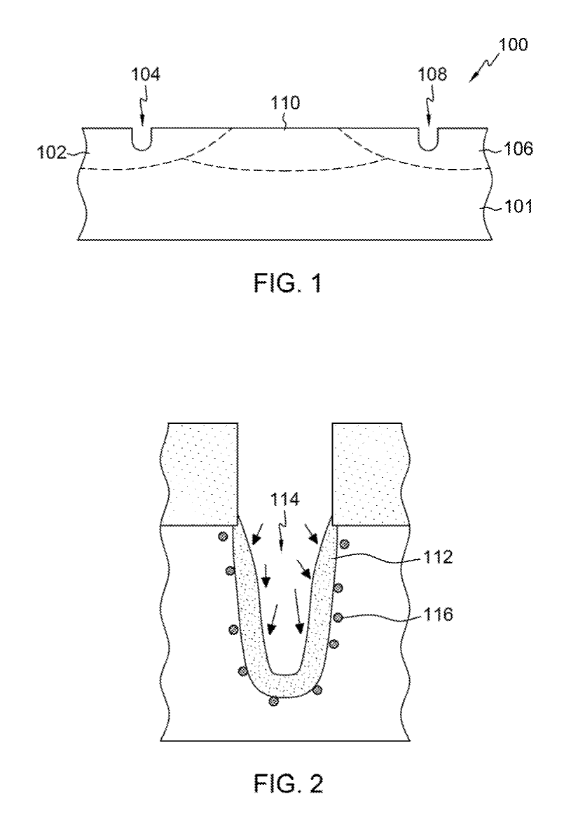

FIG. 1 is a cross-sectional view of one example of a transistor 100 in fabrication, the transistor including a semiconductor substrate 101, a n-type source region 102 with trench 104 therein, and a n-type drain region 106 with trench 108 therein. The trenches are formed to house epitaxial semiconductor material for stressing a channel region 110, in accordance with one or more aspects of the present invention.

The starting structure may be conventionally fabricated, for example, using known processes and techniques. However, although only a portion is shown for simplicity, it will be understood that, in practice, many such structures are typically included on the same bulk substrate.

In one example, substrate 101 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

FIG. 2 depicts one example of the source/regions (102, 106) of FIG. 1 (both look the same) after forming a relatively thick buffer layer 112 (e.g., about 4 nm to about 70 nm in thickness) of, for example, phosphorus-doped epitaxial silicon carbon, in accordance with one or more aspects of the present invention, prior to the introduction of hydrochloric acid 114 (more generally, halogens) at high temperatures during subsequent nFET source/drain epitaxy process. The buffer layer reduces or eliminates interaction between any metal contaminants 116 that may be present below surfaces of the source region and/or drain region, and the subsequent hydrochloric acid present during epitaxial growth. Thus, the buffer layer retards wormhole formation. After forming the buffer layer, normal fabrication of the sources and drains may resume without concern for any wormholes, since the buffer layer reduces or eliminates creation of wormholes. Note that, rather than testing for contaminants, a buffer layer may be added to all n-type sources and drains as a preventative measure.

As one skilled in the art will know, contaminants 116 typically come from various process steps before formation of the buffer layer; thus, the contaminants are randomly distributed. The contaminants may be elemental metal nanoparticles, which typically come from lithographic processing (resist, developer) and other organic solvents. Metal contaminants also come from tools/chambers and also cross-contamination with other process steps. The contaminants are not part of the buffer layer, but just below surfaces of the trenches. The buffer layer is deposited such that the contaminants do not get in contact with high temperature hydrochloric acid used during SiC EPI process used to form the source/drain. The interaction of hydrochloric acid (HCl) with metal particles (transition metals especially, Fe, Ni) causes silicon tunnels, aka wormholes, being etched in silicon-on-insulator structures. The above process is intended to be done in all open n-type source and drain areas at the same time as a preventative measure.

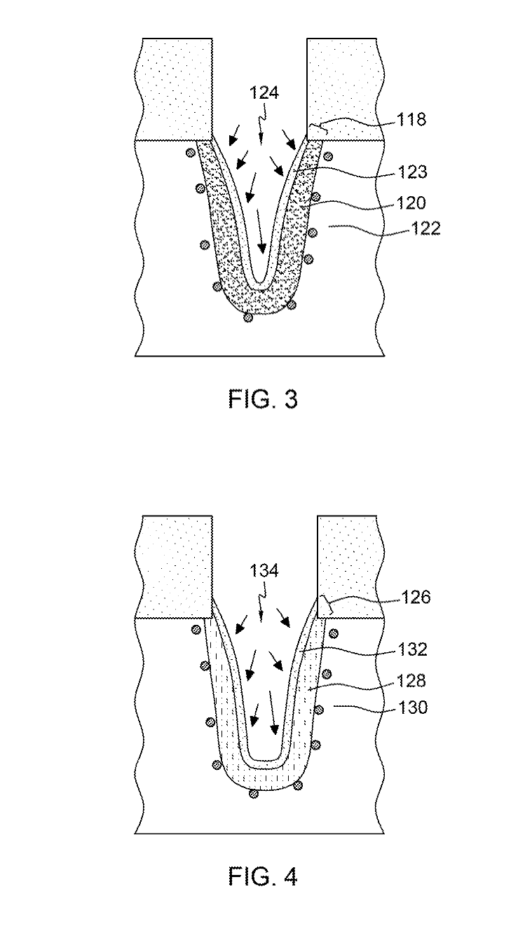

FIG. 3 depicts another example of the source/drain regions (102, 106) of FIG. 1 after forming a buffer layer 118, in accordance with one or more aspects of the present invention. The buffer layer includes a relatively thick bottom layer 120 of phosphorus-doped silicon covering surfaces of the source trenches and drain trenches, the bottom layer having a thickness of, for example, about 0.5 nm to about 12 nm. The buffer layer also includes a top layer 123 of phosphorus-doped epitaxial silicon carbon over the bottom layer, the buffer layer formed prior to the introduction of hydrochloric acid 124 at high temperatures during nFET source/drain epitaxy process. The buffer layer reduces or eliminates interaction between hydrochloric acid present during epitaxial growth and any metal contaminants 122 that may be present below the source/drain trench surfaces. After forming the buffer layer, normal fabrication of the sources and drains may resume without concern for any wormholes. Note that, rather than testing for possible existence of contaminants, a buffer layer may be added to all n-type sources and drains as a preventative measure, since the buffer layer reduces or eliminates creation of wormholes.

FIG. 4 depicts still another example of the source/drain regions (102, 106) of FIG. 1 after forming a buffer layer 126 over surfaces of the source trench and drain trench, in accordance with one or more aspects of the present invention. The buffer layer includes, for example, a bottom layer 128 of undoped epitaxial silicon carbon, and a top layer 132 of phosphorus-doped epitaxial silicon carbon. The buffer layer is formed prior to the introduction of hydrochloric acid 134 at high temperatures during nFET source and drain epitaxy process. The buffer layer reduces or eliminates interaction between metal contaminants 130 that may be present below surfaces of the trenches and the hydrochloric acid. After forming the buffer layer, normal fabrication of the sources and drains may resume without concern for any wormholes, since the buffer layer reduces or eliminates creation of wormholes by separating and so preventing metal contaminants from possibly contacting/interacting with hydrochloric acid (more generally, halogens). Note that, rather than testing for any existence of metal contaminants, a buffer layer may be added to all n-type sources and drains as a preventative measure.

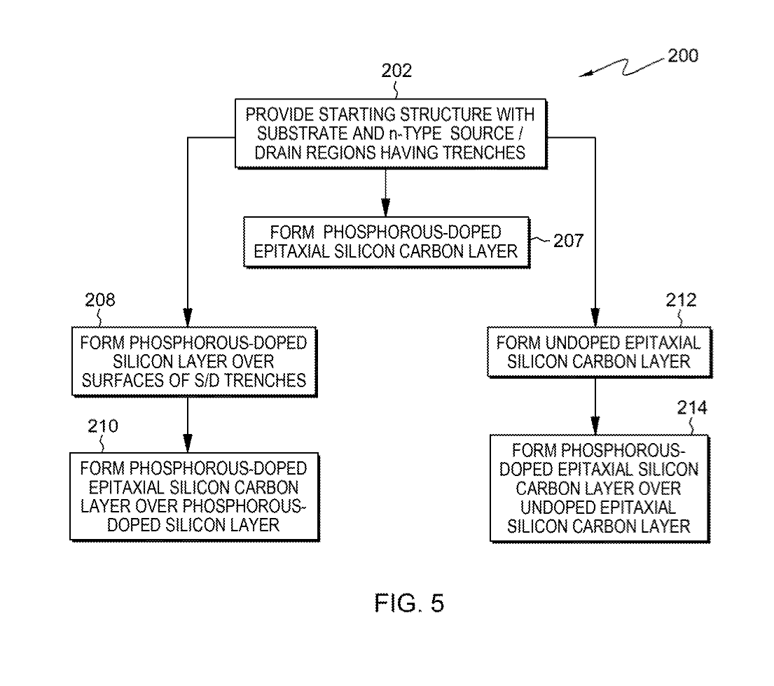

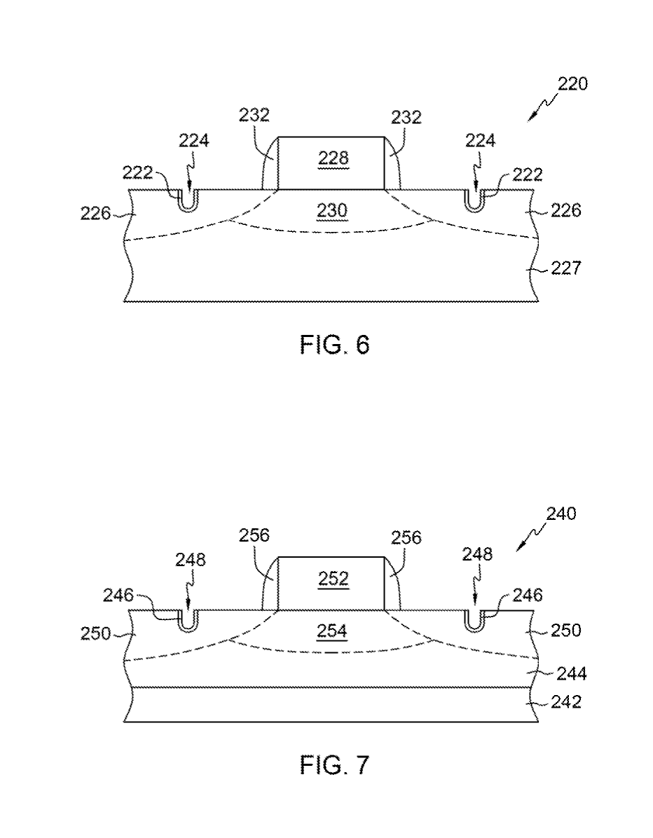

FIG. 5 is one example of a flow diagram 200 describing aspects of the method of the present invention. Initially, a starting structure is provided having a substrate and n-type source and drain regions at step 202 (see FIG. 1) with trenches therein (see FIG. 1). A buffer layer is formed that is, in general, sufficiently thick to inhibit metal contaminant/halogen interaction in subsequent processes of forming a source and a drain. The buffer layer is formed, for example, in one of three ways at step 207, steps 208 and 210, or steps 212 and 214 (see FIGS. 2-4 for examples). Step 202 is common to all three examples of FIGS. 2-4.

The buffer layer may be formed, for example, by forming a layer of phosphorous-doped epitaxial silicon carbon over the source and drain trenches at step 207, or, for example, by forming a phosphorous-doped silicon layer over surfaces of the source and drain trenches at step 208, followed by a phosphorous-doped epitaxial silicon-carbon layer over the phosphorous-doped silicon layer at step 210 (see FIG. 2), or, alternatively, the buffer layer may be formed by forming an undoped epitaxial silicon-carbon layer at step 212, followed by a phosphorous-doped epitaxial silicon-carbon layer over the undoped epitaxial silicon-carbon layer at step 214, in accordance with one or more aspects of the present invention.

FIG. 6 depicts one example of a simplified n-type planar transistor 220 including a buffer layer 222 of the present invention in source/drain trenches 224 and in source/drain regions 226. The transistor also includes a semiconductor substrate 227, a gate 228 covering a channel 230, the gate having a pair of spacers 232. Note that the buffer layer is generalized to represent any of those depicted in FIGS. 2-4, in accordance with one or more aspects of the present invention.

FIG. 7 depicts one example of a simplified n-type FinFET 240 including a semiconductor substrate 242 and semiconductor fin 244. The FinFET further includes a buffer layer 246 of the present invention in source/drain trenches 248 and in source/drain regions 250. The transistor also includes a semiconductor substrate 251, a gate 252 covering a channel 254, the gate having a pair of spacers 256. Note that the buffer layer represents any of those depicted in FIGS. 2-4, in accordance with one or more aspects of the present invention.

In a first aspect, disclosed above is a method. The method includes providing a starting structure, the starting structure including a semiconductor substrate, a n-type source region and a n-type drain region of a transistor in the semiconductor substrate. The method further includes removing a portion of the n-type source region and a portion of the n-type drain region, creating a source trench and a drain trench, and forming a buffer layer over a surface of the source trench and the drain trench, the buffer layer being sufficiently thick to inhibit interaction between metal contaminants that may be present below surfaces of the n-type source trench and/or the n-type drain trench, and halogens during a subsequent process.

In one example, the buffer layer may include, for example, phosphorous-doped epitaxial silicon carbon. In one example, the phosphorous-doped epitaxial silicon carbon may have, for example, a thickness of between about 4 nm and about 70 nm.

In one example, forming the buffer layer in the method of the first aspect may include, for example, forming a phosphorous-doped silicon layer over surfaces of the source trench and the drain trench, and forming a phosphorous-doped epitaxial layer of silicon carbon on the phosphorous-doped silicon layer. In one example, the phosphorous-doped silicon layer may have, for example, a thickness of about 0.5 nm to about 12 nm.

In one example, forming the buffer layer in the method of the first aspect may include, for example, forming an undoped epitaxial silicon-carbon layer, and forming a phosphorous-doped epitaxial silicon-carbon layer over the undoped epitaxial silicon-carbon layer.

In a second aspect, disclosed above is a semiconductor structure. the semiconductor structure includes a semiconductor substrate, a n-type source region having a source trench, and a n-type drain region having a drain trench. Metal contaminant(s) may be present below surfaces of the source trench and/or the drain trench. The semiconductor structure further includes a buffer layer covering the surfaces of the source trench and the drain trench.

In one example, the buffer layer may include, for example, phosphorous-doped epitaxial silicon carbon. In one example, the phosphorous-doped epitaxial silicon carbon may have, for example, a thickness of between about 4 nm and about 70 nm.

In one example, the buffer layer of the semiconductor structure of the second aspect may include, for example, a bottom layer of phosphorous-doped silicon covering surfaces of the source trench and the drain trench, and a top layer of phosphorous-doped epitaxial silicon carbon over the bottom layer of phosphorous-doped silicon.

In one example, the phosphorous-doped epitaxial silicon-carbon layer may have, for example, a thickness of about 4 nm and about 70 nm.

In one example, the buffer layer of the semiconductor structure of the second aspect and may include, for example, an undoped epitaxial silicon-carbon layer covering surfaces of the source trench and the drain trench, and a phosphorous-doped epitaxial silicon-carbon layer over the undoped epitaxial silicon-carbon layer.

In one example, the semiconductor structure of the second aspect may be, for example, part of a planar transistor.

In one example, the semiconductor structure of the second aspect may be, for example, part of a FinFET.

In one example, the semiconductor structure of the second aspect may further include, for example, a source in the source trench and a drain in the drain trench.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting structure, the starting structure comprising a semiconductor substrate, a n-type source region and a n-type drain region of a transistor in the semiconductor substrate;
removing a portion of the n-type source region and a portion of the n-type drain region, creating a source trench and a drain trench; and
forming a buffer layer over a surface of the source trench and the drain trench, the buffer layer being sufficiently thick to inhibit interaction between metal contaminants that may be present below surfaces of the n-type source trench and/or the n-type drain trench, and halogens during a subsequent process.

2. The method of claim 1, wherein the buffer layer comprises phosphorous-doped epitaxial silicon carbon.

3. The method of claim 2, wherein the phosphorous-doped epitaxial silicon carbon has a thickness of between about 4 nm and about 70 nm.

4. The method of claim 1, wherein forming the buffer layer comprises:
forming a phosphorous-doped silicon layer over surfaces of the source trench and the drain trench; and
forming a phosphorous-doped epitaxial layer of silicon carbon on the phosphorous-doped silicon layer.

5. The method of claim 4, wherein the phosphorous-doped silicon layer has a thickness of about 0.5 nm to about 12 nm.

6. The method of claim 1, wherein forming the buffer layer comprises:
forming an undoped epitaxial silicon-carbon layer; and
forming a phosphorous-doped epitaxial silicon-carbon layer over the undoped epitaxial silicon-carbon layer.

7. A semiconductor structure, comprising:
a semiconductor substrate;
a n-type source region having a source trench;
a n-type drain region having a drain trench;
a buffer layer covering the surfaces of the source trench and the drain trench, wherein the buffer layer prevents one or more metal contaminants below surfaces of the at least one of the source trench and the drain trench from interacting with hydrochloric acid, and wherein there is an absence of a source and a drain.

8. The semiconductor structure of claim 7, wherein the buffer layer comprises phosphorous-doped epitaxial silicon carbon.

9. The semiconductor structure of claim 8, wherein the phosphorous-doped epitaxial silicon carbon has a thickness of between about 4 nm and about 70 nm.

10. The semiconductor structure of claim 7, wherein the buffer layer comprises:
a bottom layer of phosphorous-doped silicon covering surfaces of the source trench and the drain trench; and
a top layer of phosphorous-doped epitaxial silicon carbon over the bottom layer of phosphorous-doped silicon.

11. The semiconductor structure of claim 10, wherein the phosphorous-doped epitaxial silicon-carbon layer has a thickness of about 4 nm to about 70 nm.

12. The semiconductor structure of claim 7, wherein the buffer layer comprises:
an undoped epitaxial silicon-carbon layer covering surfaces of the source trench and the drain trench; and
a phosphorous-doped epitaxial silicon-carbon layer over the undoped epitaxial silicon-carbon layer.

13. The semiconductor structure of claim 7, wherein the semiconductor structure is part of a planar transistor.

14. The semiconductor structure of claim 7, wherein the semiconductor structure is part of a FinFET.

15. The semiconductor structure of claim 7, further comprising a source in the source trench and a drain in the drain trench.
